(19) United States
(12) Patent Application Publication
(10) Pub. No.: US 2026/0214823 A1
(43) Pub. Date: Jul. 23, 2026

(54) ELECTRONIC DISPLAY PANEL, PARTICULARLY FOR A SPORTING EVENT, COMPRISING A DETACHABLE DECORATIVE COVER

(71) Applicant: Swiss Timing LTD, Corgémont (CH)

(72) Inventors: Regis MENOUX, Saint-Imier (CH); Valentin WEGMANN, St. Ursen (CH); Michael THOMASIUS, Leipzig (DE)

(73) Assignee: Swiss Timing LTD, Corgémont (CH)

(21) Appl. No.: 19/444,329

(22) Filed: Jan. 9, 2026

(30) Foreign Application Priority Data
Jan. 23, 2025 (EP) 25153667.8

(51) Int. Cl. H05K 5/03

(52) U.S. Cl. CPC H05K 5/03

(57) ABSTRACT

An electronic display panel (1) for a sporting event, including a frame (2) intended to be hung to suspend the display panel (1), and a display screen (3) fitted on the frame (2), the display panel (1) including a detachable decorative cover (4) designed to be fitted on the frame (2) to conceal it, and detachable fastening means (5) for attaching the decorative cover (4, 40) to the frame (2), the frame (2) and the decorative cover (4) being at least partially circular in shape to be able to slide the decorative cover (4) rotationally on the frame (2) between two positions, a first positioning position, in which the detachable fastening means (5) enable the decorative cover (4) to be positioned against the frame (2), and a second assembly position in which the detachable fastening means (5) attach the decorative cover (4) and the frame (2) to each other.

### CROSS-REFERENCE TO RELATED APPLICATIONS

This application claims priority to European Patent Application No. 25153667.8, filed on January 23, 2025, the entire contents of which are incorporated herein by reference.

### Technical field of the invention

The invention relates to an electronic display panel, in particular for a sporting event, the display panel comprising a detachable decorative cover.

### Technological background

At sporting events, an electronic display panel is often used to show spectators and players specific information, such as the score and/or the playing time.

Such a display panel is particularly important in certain sports in which a limited amount of playing time is allocated in turn to one or other team. For example, in a basketball game, each team is permitted to have possession of the ball for a limited time (currently 24 seconds). The display panel counts down the time remaining for the team to try and score a basket. Moreover, the display panel displays the playing time and preferably the score between the teams.

The display panel comprises a frame designed to be hung to suspend the display panel, for example so it can be mounted above a basketball hoop. The display panel also comprises at least one display screen fitted to the frame. For example, at least one part of the frame surrounds the display screen and outlines the display panel.

In basketball, particularly in the U.S. NBA league, display panels are generally square. The frame surrounding the display screen is therefore square in shape.

To enhance the aesthetics of these display panels, a decorative cover is placed over the frame to conceal it. In this way, the decorative cover at least partially surrounds the display screen. The decorative cover is fastened to the frame by conventional fastening means, such as screws.

To make the display panel even more attractive, the decorative cover comprises patterns or colours, for example representing a particular team or sporting event.

It is therefore necessary to change the decorative cover for certain games, or even for each game, in order to provide a decoration specific to the sporting event.

However, the fastening means used are impractical and do not enable the decorative cover to be changed quickly.

### SUMMARY OF THE INVENTION

The invention aims to make it easier to change decorative covers on display panels, particularly for sporting events.

To this end, the invention relates to an electronic display panel, in particular for a sporting event, comprising a frame intended to be hung to suspend the display panel, and a display screen fitted on the frame, the display panel comprising a detachable decorative cover designed to be fitted on the frame to conceal it, and detachable fastening means for attaching the decorative cover to the frame.

A remarkable feature of the invention is that the frame and the decorative cover are at least partially circular in shape to be able to slide the decorative cover rotationally on the frame between two positions, a first positioning position, in which the detachable fastening means enable the decorative cover to be positioned against the frame, and a second assembly position in which the detachable fastening means attach the decorative cover and the frame to each other.

Thus, due to the circular shape of the frame and of the decorative cover, the decorative cover can slide rotationally on the frame in a circular movement. This feature makes it possible to use fastening means in which, in a first positioning position, the decorative cover is positioned on the frame, and in a second assembly position, the decorative cover and the frame are attached to each other.

As a result of the invention, the decorative cover can be assembled or separated from the armature quickly and easily, by sliding the decorative cover rotationally on the armature in one direction to assemble them, and in the opposite direction to separate them.

According to a particular embodiment of the invention, the fastening means comprise a plurality of holes distributed over a front face of the frame, and a plurality of studs arranged on a rear face of the decorative cover, each stud engaging with a hole in the first positioning position and in the second assembly position.

According to a particular embodiment of the invention, the holes comprise a positioning portion with an enlarged opening and an assembly portion with a smaller opening.

According to a particular embodiment of the invention, the studs comprise a body extending from the rear face and a head that is wider than the body.

According to a particular embodiment of the invention, the head of the studs is wider than the smaller opening of the assembly portion and narrower than the enlarged opening of the positioning portion.

According to a particular embodiment of the invention, the body of the studs is narrower than both the smaller opening of the assembly portion and the enlarged opening of the positioning portion.

According to a particular embodiment of the invention, the display panel further comprises bolting means for holding the decorative cover in the assembled position to keep it from rotating.

According to a particular embodiment of the invention, the bolting means comprise a first bolting hole arranged through the upper face of the decorative cover, and a second bolting hole arranged through the upper face of the frame, as well as a detachable latch configured to be inserted into the first and second bolting holes.

According to a particular embodiment of the invention, the first bolting hole and the second bolting hole are facing each other, when the decorative cover is in the assembly position on the frame.

According to a particular embodiment of the invention, the decorative cover is in the form of a ring.

According to a particular embodiment of the invention, the frame and the decorative cover surround the first display screen in its entirety.

According to a particular embodiment of the invention, the display panel comprises means for hanging it up.

According to a particular embodiment of the invention, the display panel comprises a second display screen arranged beneath the first display screen.

According to a particular embodiment of the invention, the decorative cover comprises a rectangular part designed to surround the second display screen.

According to a particular embodiment of the invention, the display panel comprises suspension means so that it can be hung up.

### BRIEF DESCRIPTION OF THE FIGURES

The purposes, advantages and characteristics of the invention will be better understood on reading the following detailed description, with reference to the appended drawings, in which:

FIG. 1 is a schematic representation of a front view of a display panel according to a first embodiment of the invention, in a configuration in which the decorative cover is assembled on the frame;

FIG. 2 is a schematic representation of a perspective view of the display panel in FIG. 1;

FIG. 3 is a schematic representation of a perspective view of the display panel in FIG. 1, in a configuration in which the decorative cover is detached from the frame;

FIG. 4 is a schematic representation of an enlarged perspective view of part of the display panel in a configuration in which the decorative cover is detached from the frame;

FIG. 5 is a schematic representation of an enlarged front view of one part of the fastening means;

FIG. 6 is a schematic representation of an enlarged front view of the other part of the fastening means;

FIG. 7 is a schematic close-up representation of the means for bolting the display panel; and

FIG. 8 is a schematic representation of a perspective view of a display panel according to a second embodiment of the invention in a configuration in which the decorative cover is detached from the frame.

### DETAILED DESCRIPTION OF THE INVENTION

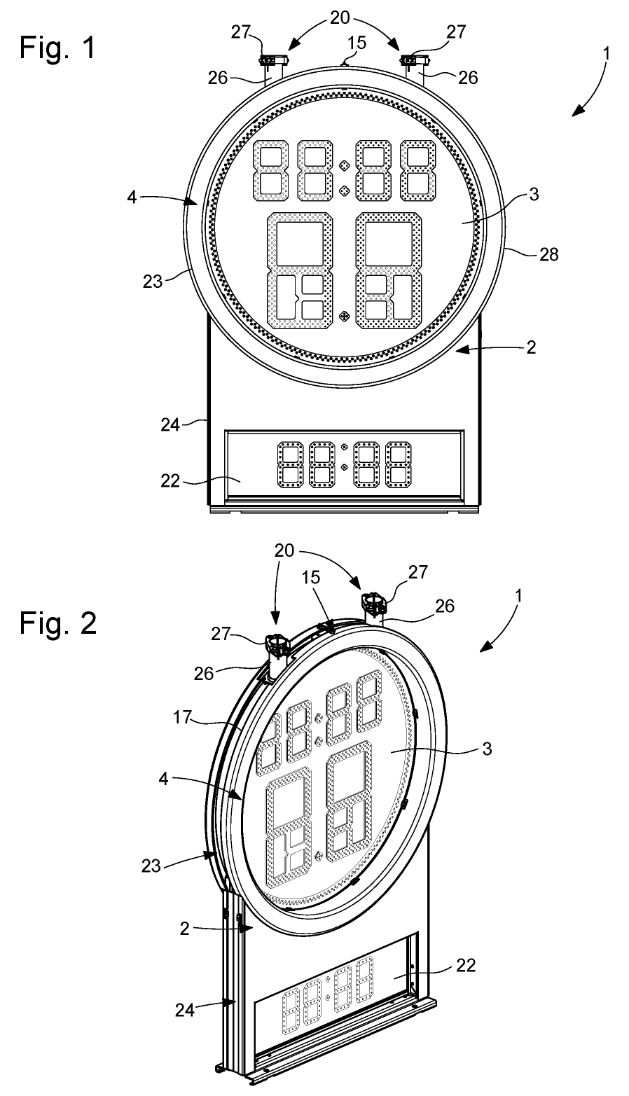

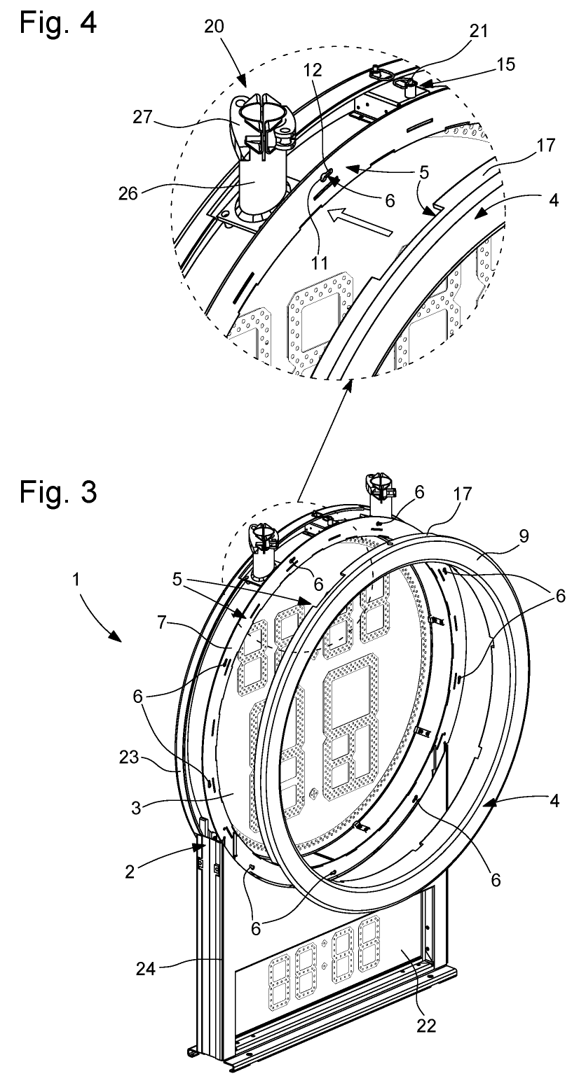

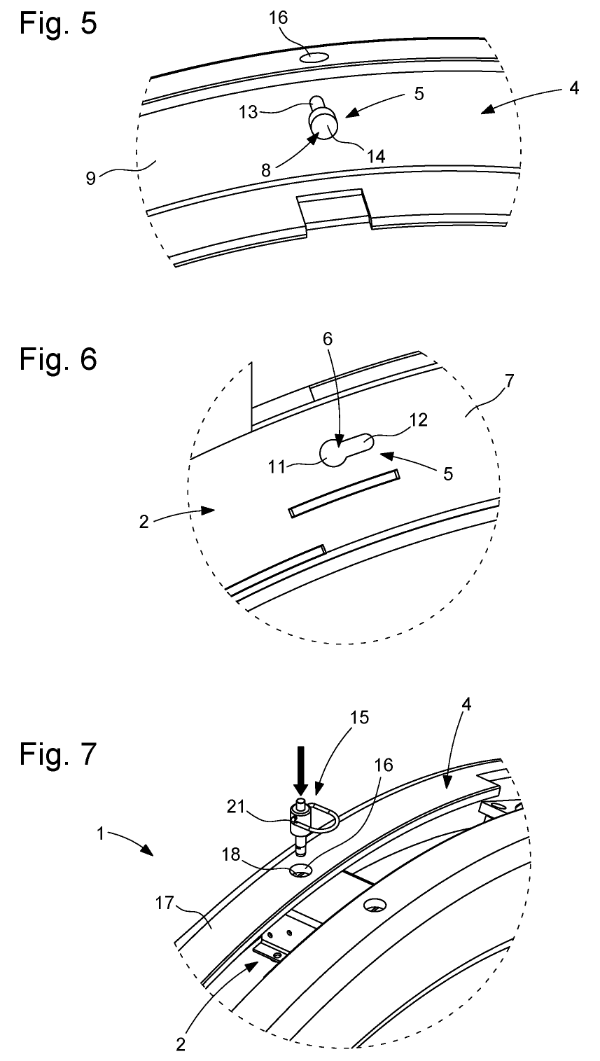

In FIGS. 1 to 7, the invention relates to a first exemplary embodiment of an electronic display panel 1, particularly for a sporting event, the display panel 1 being configured, for example, to display a score and/or a time, in particular for a basketball game.

The display panel 1 comprises a frame 2 designed to be hung to suspend the display panel 1, for example so it can be mounted above a basketball hoop, and a first display screen 3 fitted to the frame 2. For example, the first display screen 3 is used to display one or more game time countdowns.

The first display screen 3 is circular, and is surrounded by the frame 2, which comprises a circular part 23.

In this embodiment, the display panel 1 comprises a second display screen 22 arranged below the first display screen 3. The second display screen 22 is rectangular and is also surrounded by the frame 2, which comprises a rectangular part 24 arranged below the circular part 23.

The display panel 1 comprises suspension means 20 for hanging it up, for example above the basketball hoop. In the figures, the suspension means 20 comprise two tubes 26 arranged above the frame 2 and a system 27 for clamping the tubes 26 around an arm inserted into the tubes 26. The clamping system 27 comprises a lever configured to clamp the end of the tubes, the ends being cut into two longitudinal parts separated by a gap, the two parts being able to be brought closer together by the clamping means.

The display panel 1 also comprises an electronic device (not shown in the figures) for controlling and actuating the display of information on the first display screen. The electronic device is preferably housed in a compartment of the frame 2 and is electrically connected to the first display screen 3.

The display panel 1 further comprises a detachable decorative cover 4 that can be fitted to the frame 2 to conceal it.

The display panel 1 also comprises detachable fastening means 5 for attaching the decorative cover 4 to the frame 2, the fastening means 5 being arranged on the frame 2 and on the decorative cover 4.

According to the invention, the frame 2 and the decorative cover 4 are at least partially circular in shape so that the decorative cover 4 can be rotated on the frame 2 between two positions. A first position for positioning the decorative cover 4 on the frame 2, in which the fastening means 5 are engaged to position the decorative cover 4 on the frame 2, and a second assembly position in which the decorative cover 4 and the frame 2 are attached to each other.

The decorative cover 4 is in the form of a circular ring, corresponding substantially to the circular part 23 of the frame 2. These circular shapes enable the decorative cover 4 to slide over a front face 7 of the frame. The frame 2 and the decorative cover 4 therefore surround the first display screen 3.

The decorative cover 4 comprises a lateral wall 17, designed to at least partially surround the frame 2.

The fastening means 5 comprise a plurality of holes 6 distributed over the front face 7 of the frame 2 and a plurality of studs 8 arranged on a rear face of the decorative cover 4. Preferably, the holes 6 and the studs 8 are evenly spaced at an angle around the first display screen 3, respectively on the frame 2 and on the decorative cover 4.

They are arranged so that each stud 8 engages a hole 6 in the first positioning position and also in the second assembly position.

To this end, the holes 6 comprise a positioning portion with an enlarged opening 11 and an assembly portion with a smaller opening 12. The two openings, 11, 12, are contiguous and continuous for each hole 6.

The studs 6 comprise a body 13 extending from the rear face 9 of the decorative cover 4 and a head 14 that is wider than the body 13. The head 14 of the studs 6 is wider than the smaller opening 12 of the assembly portion and narrower than the enlarged opening 11 of the positioning portion. Whereas the body 13 of the studs 8 is narrower than the smaller opening 12 of the assembly portion and narrower than the enlarged opening 11 of the positioning portion.

Thus, in the first positioning position, the studs 8 are inserted into the enlarged opening 11 of the holes 6. Then, when the decorative cover 4 is rotated on the frame 2, the studs 8 slide into the smaller opening 12, so that the decorative cover 4 and the frame 2 are attached to each other, as the studs 8 can no longer exit the holes 6, their heads 14 being retained by the rim of the smaller opening 12.

The display panel 1 further comprises bolting means 15 for holding the decorative cover 4 in the assembly position, in particular to keep it from rotating in the opposite direction and prevent it from being returned to the first positioning position. In this embodiment, the bolting means 15 are arranged on top of the display panel 1.

The bolting means 15 comprise a first bolting hole 16 arranged through the lateral wall 17 of the decorative cover 4, and a second bolting hole 18 arranged on an upper face 19 of the frame 2.

The first bolting hole 16 and the second bolting hole 18 are arranged so that they are facing each other when the decorative cover 4 is in the second assembly position.

In addition, the bolting means 15 comprise a detachable latch 21 configured to be inserted into the first 16 bolting hole and the second 18 bolting hole when they are facing each other. When the frame 2 and decorative cover 4 are in the second assembly position, the latch 21 can be inserted through the first 16 bolting hole and the second 18 bolting hole, and remains in this arrangement. The latch 21 therefore holds the decorative cover 4 at an angle, so that it can no longer rotate to return to the first positioning position.

The decorative cover 4 is thereby bolted to the frame 2, as it is held at an angle by the bolting means 15, and is held axially by the fastening means 5.

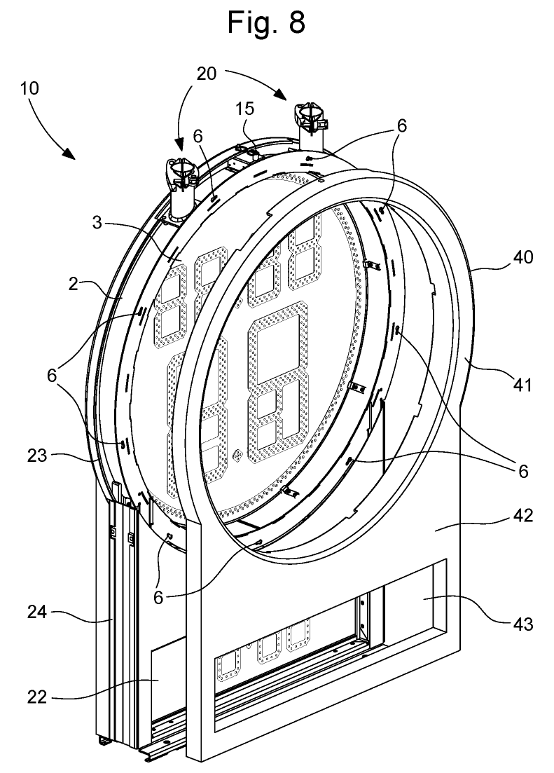

In the second embodiment in FIG. 8, the decorative cover 40 for the display panel 10 comprises a rectangular part 42 below the ring 41, which can be placed on the rectangular part 24 of the frame 2 around the second display screen 22, when the decorative cover 40 is in the assembly position. The rectangular part 42 comprises a through opening 43 enabling the second display screen 22 to be seen. Apart from the decorative cover 40, the other characteristics of the display panel 10 are identical to those of the first embodiment of the display panel 1, in particular for the attachment means 5 and the frame 2.

The display panels 1, 10 in these two embodiments can comprise two decorative covers, one on each side of the frame 2, particularly if the screens can be read on both sides.

Naturally, the invention is not limited to the embodiments described with reference to the figures, and variants could be envisaged without departing from the scope of the invention. The display panel could in fact be used in a context other than a sporting event. It can be used, for example, to display messages during a performance, in shopping malls, in car parks, on traffic lanes or in town centres.

1. An electronic display panel (1, 10) for a sporting event, comprising:
a frame (2) configured to be hung to suspend the display panel (1, 10);
a display screen (3) fitted on the frame (2);
a detachable decorative cover (4, 40) configured to be fitted on the frame (2) to conceal the frame; and
detachable fastening means (5) for attaching the decorative cover (4, 40) to the frame (2),
wherein the frame (2) and the decorative cover (4, 40) are at least partially circular in shape to be able to slide the decorative cover (4, 40) rotationally on the frame (2) between two positions, a first positioning position, in which the detachable fastening means (5) enable the decorative cover (4, 40) to be positioned against the frame (2), and a second assembly position in which the detachable fastening means (5) attach the decorative cover (4, 40) and the frame (2) to each other.

2. The display panel according to claim 1, wherein the fastening means (5) comprise a plurality of holes (6) distributed over a front face (7) of the frame (2), and a plurality of studs (8) arranged on a rear face (9) of the decorative cover (4), each stud (8) engaging with a hole (6) in the first positioning position and in the second assembly position.

3. The display panel according to claim 2, wherein the holes (6) comprise a positioning portion with an enlarged opening (11) and an assembly portion with a smaller opening (12).

4. The display panel according to claim 3, wherein the studs (8) comprise a body (13) extending from the rear face (9) and a head (14) that is wider than the body (13).

5. The display panel according to claim 4, wherein the head (14) of the studs (8) is wider than the smaller opening (12) of the assembly portion and narrower than the enlarged opening (11) of the positioning portion.

6. The display panel according to claim 5, wherein the body (13) of the studs (8) is narrower than both the smaller opening of the assembly portion and the enlarged opening (11) of the positioning portion.

7. The display panel according to claim 6, further comprising bolting means (15) for holding the decorative cover (4, 40) in the assembled position to keep it from rotating.

8. The display panel according to claim 1, wherein the bolting means (15) comprise a first bolting hole (16) arranged through an upper face (17) of the decorative cover (4, 40), and a second bolting hole (18) arranged on an upper face (19) of the frame (4), as well as a detachable latch (21) configured to be inserted into the first (16) and second (18) bolting holes.

9. The display panel according to claim 8, wherein the first bolting hole (16) and the second bolting hole (18) are facing each other, when the decorative cover (4, 40) is in the assembly position on the frame (2).

10. The display panel according to claim 1, wherein the frame (2) and the decorative cover (4) surround the first display screen (3) in its entirety.

11. The display panel according to claim 1, further comprising a second display screen (22) arranged beneath the first display screen (3).

12. The display panel according to claim 11, wherein the decorative cover (40) comprises a rectangular part (42) designed to surround the second display screen (22).

13. The display panel according to claim 1, further comprising suspension means (20) to enable the panel to be suspended.
